(19) United States
(12) Patent Application Publication
(10) Pub. No.: US 2003/0089977 A1
(43) Pub. Date: May 15, 2003

(54) Package enclosing multiple packaged chips

(75) Inventors: Soon-Shin Chee, Sunnyvale, CA (US); Leilei Zhang, Sunnyvale, CA (US)

Correspondence Address: XILINX, INC, ATTN: LEGAL DEPARTMENT, 2100 LOGIC DR, SAN JOSE, CA, 95124, US

(73) Assignee: Xilinx, Inc., San Jose, CA

(21) Appl. No.: 10/007,892

(22) Filed: Nov. 9, 2001

(51) Int. Cl. H01L 23/495

(52) U.S. Cl. 257/723

(57) ABSTRACT

A multi-package module package includes a plurality of individually packaged chips. Yield is increased over conventional multi-chip packages because the individual chips can be inexpensively and fully tested before being placed into the multi-package module package. Also, the manufacturing process is simpler because the individual chips can be more easily handled while being tested and attached to the multi-package module package. Further, a standard component surface mount process is used for package assembly. Thus, no new capital investment or process development is needed.

### FIELD OF THE INVENTION

The invention relates to packaging of integrated circuit devices, more particularly to packaging several IC chips within a single package.

### BACKGROUND

Multi-chip packages enclosing many integrated circuit dice are known in the semiconductor industry. The multi-chip package may encloses a thin printed circuit board on which several dice have been mounted. Each die is wire bonded to the printed circuit board and the printed circuit board is attached to a package base having external pins. A lid is then applied to the package. Alternatively, the multi-chip package may enclose a supportive electrically insulating substrate with surface metallization lines to which the dice are attached.

FIG. 1 shows a side cross-sectional view of a prior art multi-chip package built on a printed circuit board. Two dice D1 and D2 are attached to board B1 both mechanically and electrically. Mechanical connections are provided by paste E1 and E2. Electrical connection is made through wire bonds such as W1 through W4. Board B1 is a four-layer board including patterned conductive layers L1 through L4. The drawing is simplified to aid understanding. In FIG. 1, pad PI of die D1 is connected electrically to pad P3 of die D2. This connection is through bond wire W1, contact C1, via V51, layer 4 trace L41, via V41, layer 3 trace L31, via 43, layer 4 trace L43, via V53, contact C3, bond wire W3, ending at pad P3. Pad P4 is connected to an external solder ball SB6. This connection is through bond wire W4, contact C4, via V54, trace L44, via V44, trace L34, via V34, trace L24, via V24, trace L14, via V14 to solder ball SB6. A commercial board will typically have a more complex pattern of conductive traces and more conductive traces than those shown.

Also known are flip chip multi-chip packages in which several bare dice have solder bumps attached to their input/output pads, are flipped over, and attached to a large die, which then interconnects the bare dice to each other and connects the dice to a printed wiring board. Peripheral metallization on the large die is then attached using wire bonding or solder bumps to leads of a package.

FIG. 2 shows such a structure. In FIG. 2, an MCM package 60 includes a bi-level printed wiring board 61 provided with a stepped through-aperture 64, which is open on the bottom of the printed wiring board. The size of aperture 64 is such that when silicon substrate 18 of MCM tile 17 is placed over aperture 64, the ends of substrate 18 overlap the aperture, while chips 19 and 20 fit into the aperture 64. Solder re-flow interconnections 69 electrically connect bond fingers 67 to contacts 68. When the device is being assembled, there is no packaging material protecting chips 19 and 20. After assembly, silicon gel 29 protectively encloses interconnections between the chips and the silicon substrate and between the bond fingers on the silicon substrate and the contacts on the printed wiring board. For further discussion of such a package, see U.S. Pat. No. 5,646,828 of Degani et al., incorporated herein by reference.

Multi-chip modules (MCMS) often include a mixture of types of unpackaged dice within the chip. For example, an article by Terry Costlow in Electronic Engineering Times on Apr. 14, 1997 entitled “MCM Houses Pentium with MMX Technology” describes a package including a Pentium CPU, a PCI chip set, a RAM chip and other chips. These bare dice are attached to an interconnecting substrate formed by building up and patterning thin conductive films over PC board layers. This substrate provides connections external to the module and becomes part of a single package that encloses this mixture of dice.

One goal of multi-chip packaging is to use the smallest, shortest wiring lines or pieces of metallization between the chips in order to have the fastest communication between chips. Another goal is to minimize the size of the multi-chip module. To achieve these goals, the individual chips are conventionally not separately packaged before being placed into the MCM.

The price of MCM packages is typically high because of the cost of handling the bare dice during manufacturing and of assembling the dice into the MCM. Typically, each die is tested while it is still part of a wafer, after which, bad dice are discarded and good dice are saved for use. However, standard wafer testing is not sufficient to detect all defects that will appear in the finished product. Some flaws in the die are not detected through probe testing. Others occur as the die is further handled after testing. In some situations, only about 80% of those dice that pass the wafer test are actually found good upon final package testing. These flaws greatly reduce yield of the final product. For example, if a multi-chip package is formed using four chips, 80% of which will be good after installing in the multi-chip package, the yield of the package can be no better than 0.8×0.8×0.8×0.8=40%. Thus the incomplete testing of unpackaged chips exacts a significant penalty on yield, and therefore profit. A complete testing method to determine known good dice at the bare die level is so expensive as to again not be competitive.

An additional cost problem for MCMs is that it is expensive to attach a die to the multi-chip package substrate. The chip must be precisely registered with respect to the board to which it is attached so that wire bonds will correctly align. Registration is more difficult than in a single chip package because usually only one edge or corner of the chip is close to an edge or corner of the board to which it must be attached. Further, instead of attaching wire bonds to a lead frame of relatively large pitch, at least some of the wire bonds must be attached to the board for conducting signals to other chips in the package, and the board must have a fine pitch to allow for high density interconnections. Thus, failures during the assembly step will further reduce yield.

There is a need in the industry for less expensive methods of forming highly complex multi-chip packages.

### SUMMARY OF THE INVENTION

According to the invention, a multi-package structure includes a package within a package. Individual chips are packaged in small packages such as chip-scaled packages. Typically, these chips are tested at both the wafer and package stages. They are now protected by their packages, and will contribute very little to failure of the finally packaged device. The individually packages chips are then assembled onto an MCM substrate, which is then tested, packaged, and finally tested.

The process of the invention tests individual small packaged chips before they are packaged in the final package. When individually handled and packaged, the chips can be tested cheaply. For example, testing of packaged chips can cost only 10% as much as testing unpackaged chips. Thus, with the invention, the cost of the MCM is significantly reduced compared to prior art structures because the individual chips can be completely tested before the MCM is assembled, thus increasing the yield.

The invention makes assembly of the chips into the final package much more robust. Handling packaged chips is easier than handling bare dice required with conventional MCM assembly. The pitch of a packaged chip is larger than the pitch of pads on the bare die. Therefore, it is easier to connect the individual chps to the outer MCM package. The assembly process flow of the present invention is similar to other standard package surface mount processes. Therefore, an existing surface mount assembly line can be used, and no new capital investment is needed. Using an existing assembly process that can also be used for many other products dramatically reduces assembly cost.

The height of the small chip-size packages is so small that these packaged chips fit reasonably within another package. Furthermore, since packages are now very close in size to the size of a bare die, there is little area penalty from enclosing the individual die in a package before mounting several dice into the final package.

### BRIEF DESCRIPTION OF THE DRAWINGS

FIG. 1 shows a prior art multi-chip module illustrating electrical connection from individual chips to the lower surface of a pall grid array package.

FIG. 2 shows a prior art multi-chip module formed in an aperture of a printed wiring board as shown in Degani et al., U.S. Pat. No. 5,646,828 FIG. 6.

FIGS. 3a and 3b show top and side views of a multi-package module according to the invention.

FIG. 4 shows steps for forming a multi-package module according to the invention.

FIGS. 5a through 5d show steps according to a preferred embodiment for mounting chips to a bare board that will be the outside package.

FIG. 6 illustrates the process steps to form the inside structure illustrated in FIGS. 5a-5d.

FIGS. 7a-7d illustrate the structure in successive stages as the outside package surrounding the inner packages is completed.

FIG. 8 shows the process steps for forming the final package shown in FIGS. 7a-7d.

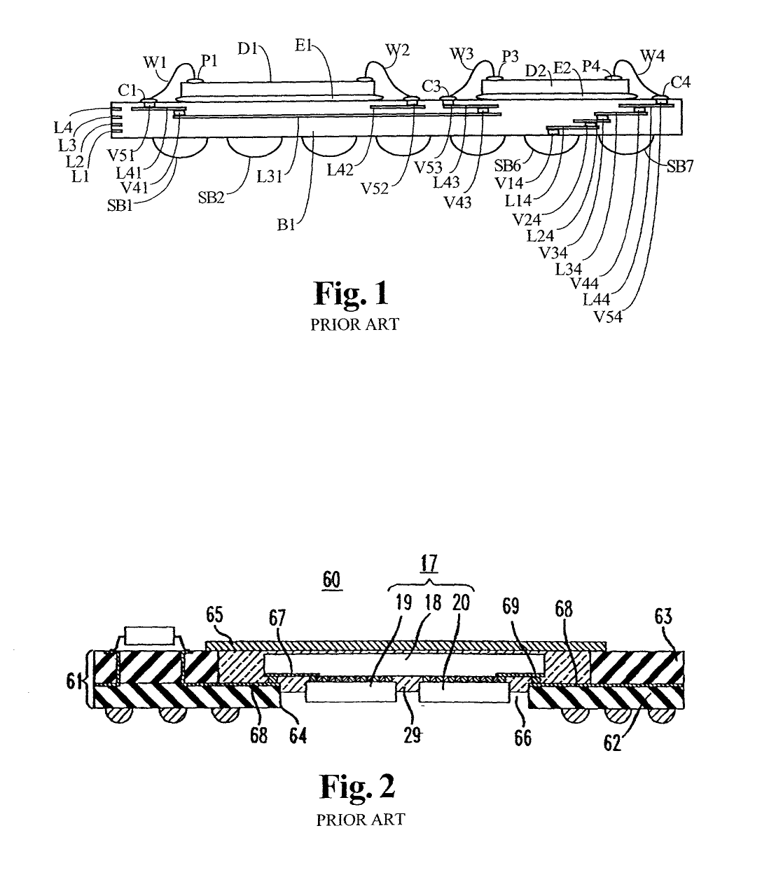

### DETAILED DESCRIPTION OF THE DRAWINGS

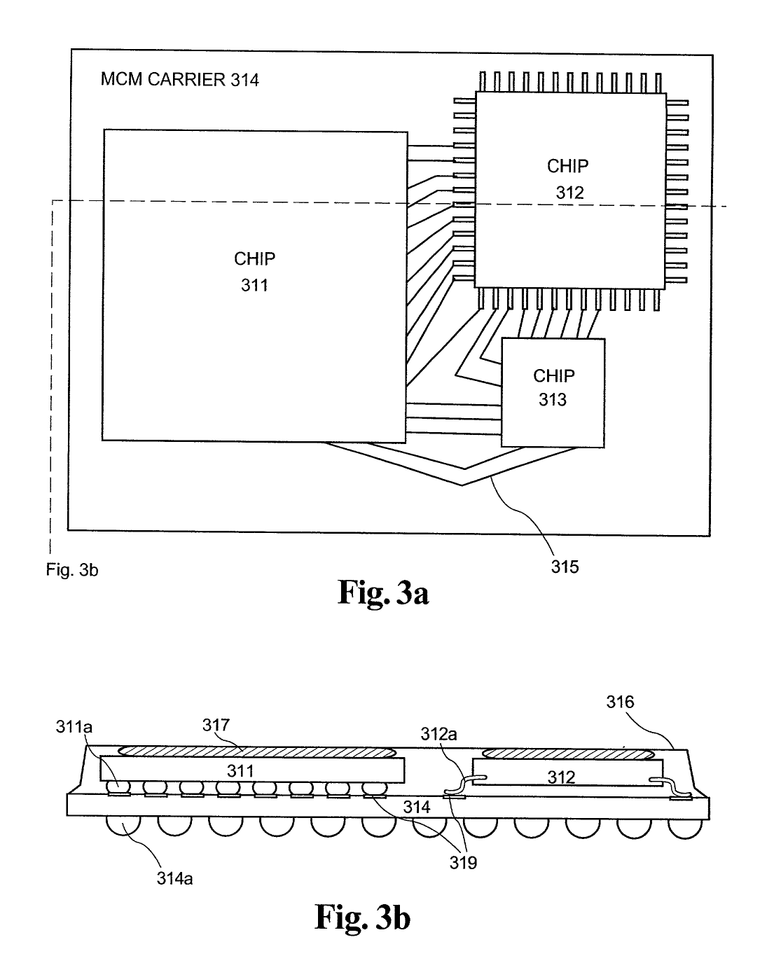

FIGS. 3a and 3b show top and side views of a multi-package module according to the invention. The particular embodiment shown includes three packaged chips 311, 312, and 313 mounted on a multi-package board 314. Chip 311 and 313 are packaged in ball grid array packages and chip 312 is packaged in a thin plastic quad flat package. In one example, these three chips comprise an FPGA, a RAM, and a microprocessor. Any such combination of individual chips can take advantage of the present invention as long as the individual chips are placed into small form factor surface mounted packages.

MCM chip 314 includes lands 319, of which only a few are shown in FIG. 3b. Solder bumps 311a on the bottom surface of FPGA chip 311 and leads 312a extending from the side of DSP microprocessor chip 312 connect to corresponding lands 319. The lands are in turn connected via layers in MCM chip 314 to other lands which in turn connect to leads on other chips or to leads that in turn connect to one of solder bumps 314a at the exterior of the package, thus giving access between points outside the package of FIG. 3a or 3b and points inside one of the chips 311-313.

In order to improve thermal conductivity, thermal grease 317 may be applied to the upper surface of the chips 311-313 before a metal lid 316 is put into place and attached.

Another advantage of the present invention compared to MCM packages made with bare dice is that the individual chips 311-313 can be removed and repaired, replaced, or upgraded without having to discard the remainder of the MCM package.

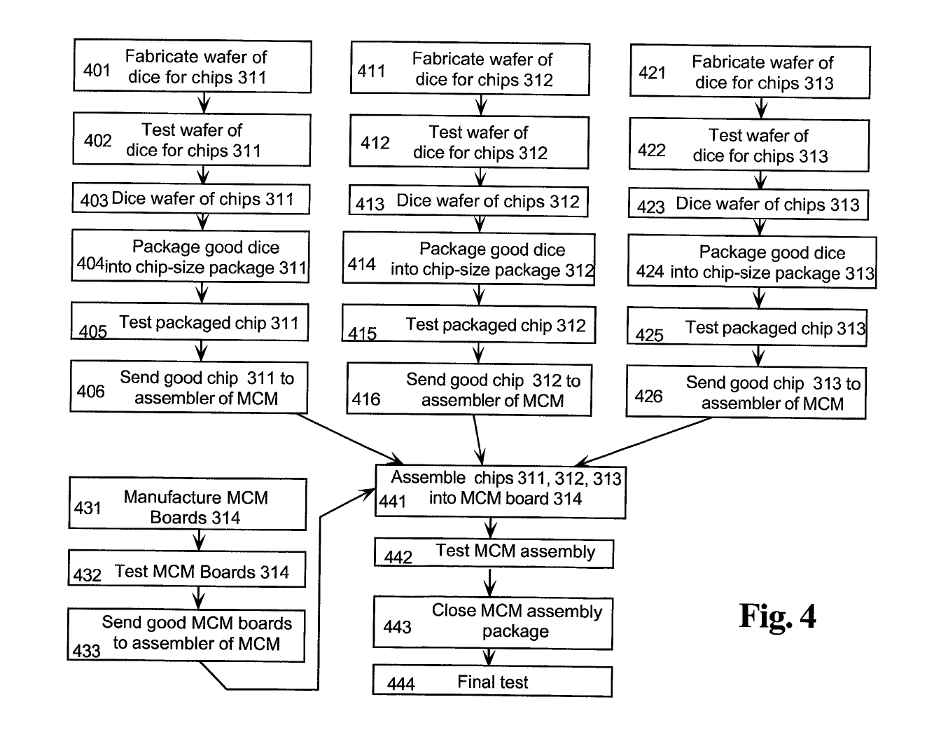

FIG. 4 shows process steps for manufacturing the MCM of FIG. 3. The upper part of the figure shows parallel steps for manufacturing, testing, packaging, and testing the three individual chips 311, 312, and 313. As steps 401-406 show, chips 311 are fabricated as part of a wafer, tested as part of the wafer, diced into individual chips, packaged, if good, into packages, preferably chip-size packages, and finally tested. This final test is a complete test and still much less expensive than a known-good-die test that would be performed on unpackaged dice. At each stage of testing only the good dice are moved to the next stage. Thus, at step 406, only good chips 311 are sent to the MCM assembler. Steps 411-416 provide only good chips 313 to the assembler, and steps 421-426 provide only good chips 312 to the assembler.

Also provided to the assembler are the MCM boards 314 into which the three chips will be placed. Steps 431-433 indicate that the MCM boards are manufactured and tested, and that only good MCM boards are sent to the assembler.

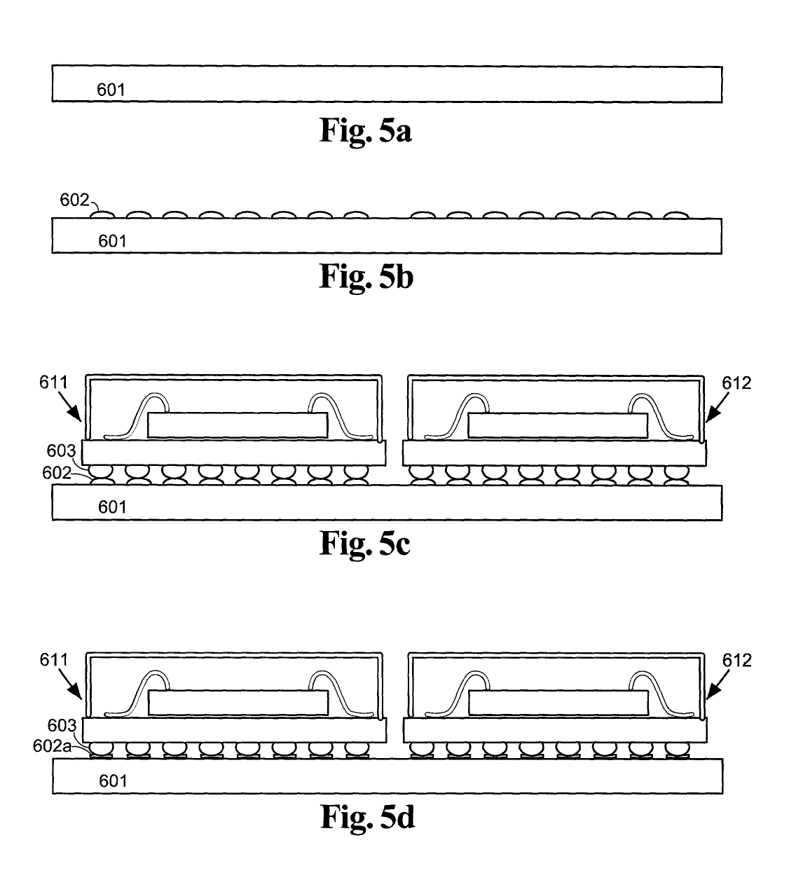

The assembly occurs at step 441. At this step, the three chips 311, 312, and 313 are carefully placed against the corresponding lands of MCM board 314. This step is easier and more reliable than forming an MCM from unpackaged chips because the solder bumps or leads are spaced further from each other and are larger than pads or solder bumps attached to die attach pads on a bare chip. (For detail, see discussion of FIGS. 5-8.) Steps 442 and 444 show that testing occurs both before and after the package is closed. Before the package is closed, it is possible to do diagnostic probe testing as well as production testing by applying test signals to external pins or solder balls of the package. In another embodiment, step 442 is bypassed and all testing of the MCM is performed after packaging step 443 is completed.

FIGS. 5a-5d illustrate steps in a preferred process for mounting packaged chips to a bare board that will form part of the outside package. As shown in FIG. 5a, the process begins with the bare board 601. As shown in FIG. 5b, solder paste 602 is applied to the bare board 601 at locations where balls of the packaged chips will be attached to board 601. As shown in FIG. 5c, the packaged chips 611 and 612 are placed against board 601 such that balls 603 of the packaged chips 611 and 612 are aligned with solder paste 602. Next, as shown in FIG. 5d, the assembly is placed into a reflow oven and brought to a temperature sufficient to melt solder paste 602 and solder balls 603 (or in another embodiment metal pins equivalent to solder balls 603), forming permanent electrical connections between balls 603 and conductors (not shown) in board 601. These electrical conductors can connect one of chips 611 and 612 to another and can connect chips 611 and 612 to external balls not yet present.

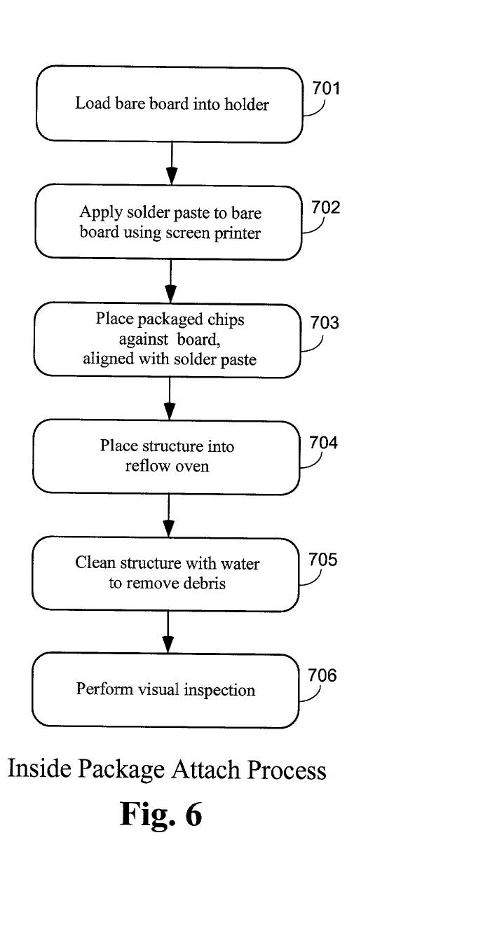

FIG. 6 illustrates the process steps to form the inside structure illustrated in FIGS. 5a-5d. At step 701, the bare board is loaded into a holder. At step 702, a screen is placed over the bare board and solder paste is applied, contacting and attaching to the board where openings are present in the screen. Next, at step 703, packaged chips are placed against the board so that balls on the lower surface of the chips align with the solder paste pattern. The structure is then placed into a reflow oven and heated until the solder paste melts sufficiently to form a good electrical and mechanical connection to the balls of the packaged chips and to the board. After the structure has cooled, at step 705, the structure is cleaned to remove any debris that may have accumulated. Finally, at step 706, a visual inspection is performed. This process is compatible with the standard surface mount process widely used in the electronic industry. No special tooling is needed for this ball grid array packaging process.

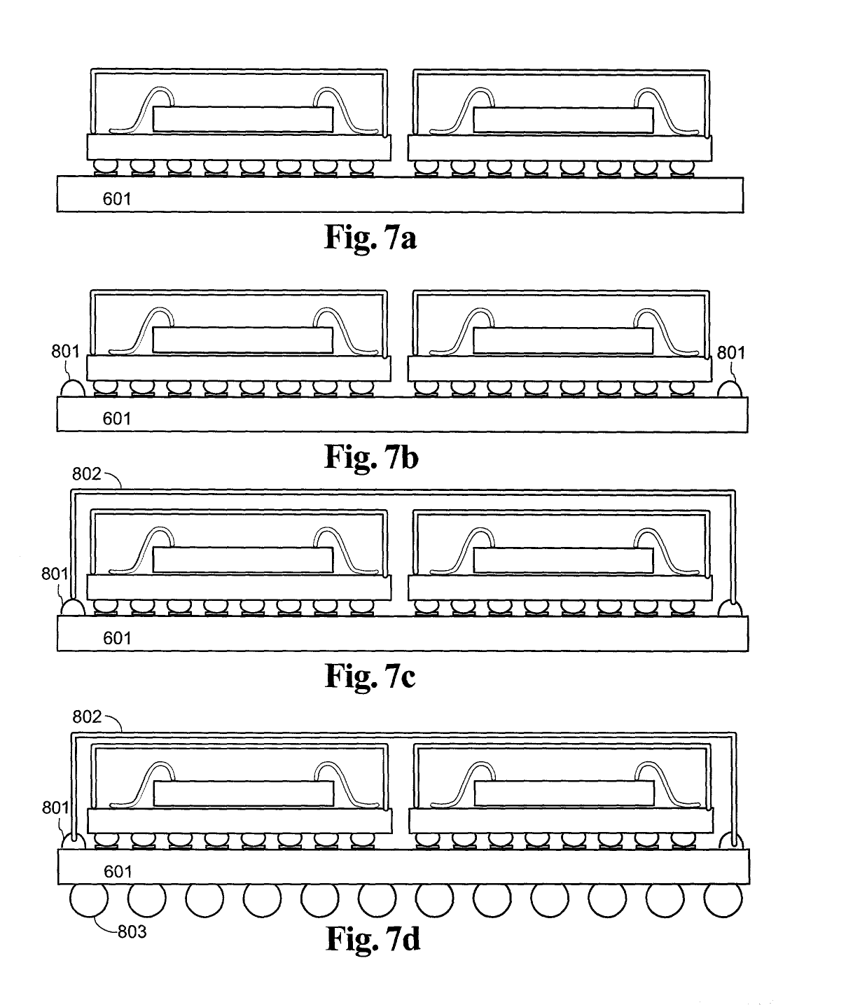

FIGS. 7a-7d illustrate the structure in successive stages as the outside package surrounding the inner packages is completed. FIG. 7a shows the structure as prepared in FIGS. 5a-5d. As shown in FIG. 7b, a rim of adhesive is applied to edges of board 601 for receiving and attaching a lid. As shown in FIG. 7c, the lid 802 is placed so that its rim contacts the rim of adhesive 801. The adhesive is cured, either by heating or by waiting or by both, depending upon the adhesive chosen. Finally, as shown in FIG. 7d, solder balls 803 are attached to the board 601, completing the outer package.

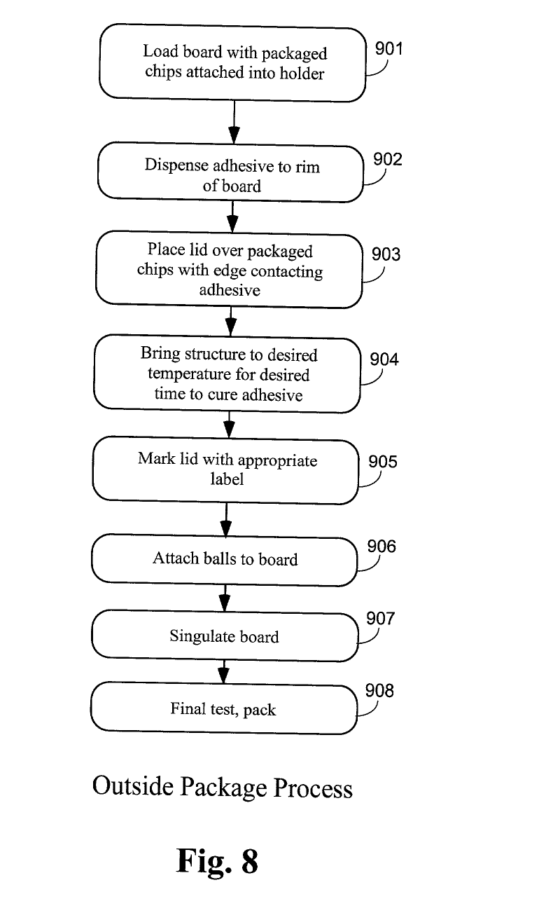

FIG. 8 shows the process steps for forming the final package shown in FIGS. 7a-7d. In step 901, the board with the packaged chips attached is placed into a holder. In step 902, a bead of adhesive is applied to the rim of the board. At step 903, the lid is put in place so that the packaged chips are enclosed and the edge of the lid is seated in the adhesive. At step 904, the adhesive is cured so that it forms a firm connection between the lid and the board. Typically, at step 905, markings are placed on the lid to identify the assembled package, though in another embodiment, the markings may be placed onto the lid before it is attached to the board. Then, at step 906, the solder balls that will make external electrical contact are attached to the board.

The next step 907 is to singulate the board. In a preferred process, a board is formed as a long strip with wiring for attaching several sets of packaged chips and lids. If the board is so made, it is cut into separate packages at step 907. Finally, at step 908, a final electrical and mechanical test, and a final visual inspection is performed, and the finished packages are packed for shipping to a customer.

The lid attach, marking, and ball attach steps are standard steps in a plastic ball grid array assembly process.

Several embodiments for making and using the invention have been described. However, the invention should not be limited to the embodiments shown here but should include variations made obvious to those skilled in the art by the above description.

1. A multi-package module comprising:
a plurality of individually packaged integrated circuit chips, each of said individually packaged integrated circuit chips including a plurality of electrically conductive contacts;
a wiring structure to which said electrically conductive contacts are attached; and
a package enclosing said individually packaged integrated circuit chips and said wiring structure, and including electrical leads extending from its interior to its exterior and electrically connecting to some of said electrically conductive contacts.

2. A multi-package module as in claim 1 wherein said conductive contacts are located at one surface of said individually packaged integrated circuit chips.

3. A multi-package module as in claim 1 wherein said electrically conductive contacts comprise solder bumps.

4. A multi-package module as in claim 1 wherein said electrically conductive contacts comprise leads extending from edges of said individually packaged integrated circuit chips.

5. A method for forming a multi-package module comprising the steps of:
manufacturing a plurality of dice to be packaged into a single module;
testing said dice with at least one die test;
packaging those of said dice that pass said die test into packaged chips;
testing said packaged chips with a chip test;
attaching a set of packaged chips to an MCM board, thereby interconnecting said set of packaged chips; and
enclosing said set of packaged chips in an outer package including said MCM board.

6. A method of manufacturing a semiconductor package enclosing a plurality of semiconductor packages comprising the steps of:
attaching a plurality of packaged integrated circuit chips to a board;
attaching a lid to the board and thereby enclosing the plurality of packaged integrated circuit chips; and
attaching a plurality of solder balls to the board.

7. The method of claim 6 wherein the step of attaching a plurality of packaged integrated circuit chips to a board comprises:
applying a pattern of solder paste to the bare board;
placing the plurality of packaged integrated circuit chips against the pattern of solder paste such that each pin of each integrated circuit chip contacts a region of solder paste; and
heating the packaged integrated circuit chips and board such that the solder paste flows against the pins and board to electrically and mechanically connect the pins to the board.

8. The method of claim 6 wherein the step of attaching a lid to the board and thereby enclosing the plurality of packaged integrated circuit chips comprises:
dispensing adhesive to at least one rim of the board;
placing the lid over the plurality of semiconductor packages such that the lid contacts the adhesive; and
curing the adhesive.

9. The method of claim 8 comprising a further step of marking the lid with an appropriate label before the step of attaching a plurality of solder balls to the board.

10. The method of claim 6 comprising a further step, after the step of attaching a plurality of solder balls to the board, of singulating the board.
